(19) United States
(12) Patent Application Publication
(10) Pub. No.: US 2009/0205182 A1
(43) Pub. Date: Aug. 20, 2009

(54) METHOD OF MANUFACTURING LIQUID EJECTION HEAD AND METHOD OF MANUFACTURING PIEZOELECTRIC ELEMENT

(75) Inventor: Takeshi SAITO, Matsumoto-shi (JP)

Correspondence Address: Workman Nydegger;1000 Eagle Gate Tower, 60 East South Temple, Salt Lake City, UT, 84111, US

(73) Assignee: Seiko Epson Corporation, Tokyo (JP)

(21) Appl. No.: 12/372,211

(22) Filed: Feb. 17, 2009

(30) Foreign Application Priority Data
Feb. 18, 2008 (JP) 2008-035656

(51) Int. Cl. H01L 41/22

(52) U.S. Cl. 29/25.35

(57) ABSTRACT

A method of manufacturing a liquid ejection head that includes a flow channel-forming substrate having pressure-generating chambers communicated with nozzle openings configured to eject liquid, and a piezoelectric element including a lower electrode film disposed in a region of the flow channel-forming substrate opposing the pressure-generating chambers, a piezoelectric layer, and an upper electrode film includes forming a lower electrode film at one side of a flow channel-forming substrate, forming a dummy layer by firing a piezoelectric material on the lower electrode film, exposing the lower electrode film by removing the dummy layer, forming a piezoelectric layer on the exposed lower electrode film, the piezoelectric layer being constituted by at least one piezoelectric film formed by conducting a piezoelectric film-forming process of firing a piezoelectric material, and forming an upper electrode film on the piezoelectric layer.

### CROSS REFERENCES TO RELATED APPLICATIONS

The entire disclosure of Japanese Patent Application No. 2008-035656, filed Feb. 18, 2008 is expressly incorporated by reference herein.

### BACKGROUND

1. Technical Field

The present invention generally relates to methods of manufacturing liquid ejection heads that eject liquid from nozzle openings and piezoelectric elements, and in particular to a method of manufacturing an ink jet recording head that ejects ink.

2. Related Art

Piezoelectric elements used in liquid ejection heads and the like are elements in which a dielectric film composed of a piezoelectric material that has an electromechanical transducer function is interposed between two electrodes. The dielectric film is composed of, for example, a crystallized piezoelectric ceramic.

Such piezoelectric elements are also used as pressure-generating units that enable ejection of liquid from nozzle openings of liquid ejection heads. A piezoelectric element is manufactured by, for example, forming a lower electrode film on one surface of a substrate (flow channel-forming substrate) by sputtering or the like, forming a piezoelectric layer on the lower electrode film by a sol-gel method, a metalorganic decomposition (MOD) method, or the like, forming an upper electrode film on the piezoelectric layer by sputtering, and patterning the piezoelectric layer and the upper electrode film (e.g., refer to Japanese Unexamined Patent Application Publication No. 2001-274472).

The sol-gel method of making the piezoelectric layer includes a process of applying a sol of an organometallic compound on the substrate on which the lower electrode film is formed, and drying and gelling (degreasing) the applied sol to form a precursor film of the piezoelectric material. This process is conducted at least once and then the precursor film is fired at a high temperature to be crystallized. By repeating this process, a piezoelectric layer (piezoelectric thin film) having a target thickness is formed.

Japanese Unexamined Patent Application Publication No. 2001-105594, for example, proposes a lower electrode film for a piezoelectric element. This lower electrode film is a composite film constituted by an adhesive layer composed of titanium, a platinum layer on the adhesive layer, and an iridium layer on the platinum layer.

However, during firing of the piezoelectric precursor film, the substrate warps due to differences in linear expansion coefficient between the substrate and layers on the substrate, and stress caused by the warpage is applied on the piezoelectric layer.

In the case where the lower electrode film is a composite of a plurality of layers as described in Japanese Unexamined Patent Application Publication No. 2001-105594, the lower electrode film is stressed by interdiffusion between layers caused by heat of firing. Due to the stress generated in the lower electrode film, the piezoelectric layer is stressed.

Furthermore, as described in Japanese Unexamined Patent Application Publication No. 2001-105594, when iridium is contained as an example of the metal constituting the lower electrode film, iridium is oxidized into iridium oxide by the heat of firing. As a result of the oxidation, the lower electrode swells, and the piezoelectric layer is stressed by warpage caused by swelling of the lower electrode film, resulting in cracking of the piezoelectric layer.

Such a problem is present not only in piezoelectric elements mounted in liquid ejection heads such as ink jet recording heads but also in other piezoelectric elements incorporated in various other devices.

### SUMMARY

An advantage of some aspects of the invention is to provide a method of a manufacturing liquid ejection head whose reliability is improved by preventing a piezoelectric layer from cracking, and a method of manufacturing a piezoelectric element.

One aspect of the invention provides a method of manufacturing a liquid ejection head that includes a flow channel-forming substrate having pressure-generating chambers communicated with nozzle openings configured to eject liquid, and a piezoelectric element including a lower electrode film disposed in a region of the flow channel-forming substrate opposing the pressure-generating chambers, a piezoelectric layer, and an upper electrode film. This method includes forming a lower electrode film at one side of a flow channel-forming substrate; forming a dummy layer by firing a piezoelectric material on the lower electrode film; exposing the lower electrode film by removing the dummy layer; forming a piezoelectric layer on the exposed lower electrode film, the piezoelectric layer being constituted by at least one piezoelectric film formed by conducting a piezoelectric film-forming process of firing a piezoelectric material; and forming an upper electrode film on the piezoelectric layer.

According to this method, the lower electrode film swells by oxidation and warps due to the swelling. The lower electrode film remains warped even after removal of the dummy layer. The piezoelectric layer is formed on the lower electrode film in the warped state. Thus, the lower electrode film does not warp further under heat applied during formation of the piezoelectric layer, and no stress is applied to the piezoelectric layer. Accordingly, the piezoelectirc layer can be prevented from cracking due to the stress, and a liquid ejection head including a highly reliable piezoelectric element can be manufactured.

The piezoelectric material used in forming the piezoelectric film is preferably a sol of an organometallic compound containing lead. The piezoelectric material used in forming the dummy layer is preferably a sol of an organometallic compound that contains no lead or lead in an amount smaller than that contained in the piezoelectric material used for forming the piezoelectric film. In this manner, lead contained in the piezoelectric layer can be suppressed from diffusing into the lower electrode film.

The lower electrode film preferably an adhesive layer on the flow channel-forming substrate, a platinum layer on the adhesive layer, and a diffusion-suppressing layer configured to suppress diffusion of lead, the diffusion-suppressing layer being disposed on the platinum layer. This structure allows of metals constituting the diffusion-suppressing layer of the lower electrode film to be oxidized and more assuredly suppresses diffusion of lead contained in the piezoelectric layer into the lower electrode film.

The method preferably further includes forming a protective film containing titanium on the diffusion-suppressing layer after forming the lower electrode film. According to such a method, the diffusion-suppressing layer as the uppermost layer of the lower electrode film is prevented from being exposed to, e.g., air and oxidized incompletely after formation of the diffusion-suppressing layer and before formation of the dummy layer. Accordingly, crystals of the piezoelectric layer can satisfactorily grow in the subsequent steps.

The method preferably further includes forming a titanium layer on the lower electrode film after removal of the dummy layer. According to this method, crystals of the piezoelectric layer can grow satisfactorily.

In forming the piezoelectric layer, the piezoelectric film-forming process is preferably repeated to form a piezoelectric layer constituted by a plurality of piezoelectric films. According to this method, a piezoelectric layer having good piezoelectric properties and a desired thickness can be formed.

In forming the piezoelectric layer, after the first piezoelectric film is formed, the lower electrode film and the piezoelectric film are preferably patterned. According to this method, crystal growth of the second and subsequent piezoelectric films progresses smoothly, and a piezoelectric layer having good crystallinity can be formed.

Another aspect of the invention provides a method of manufacturing a piezoelectric element including a lower electrode film, a piezoelectric layer, and an upper electrode film. The method includes forming a lower electrode film at one side of a substrate; forming a dummy layer by firing a piezoelectric material on the lower electrode film; exposing the lower electrode film by removing the dummy layer; forming a piezoelectric layer on the exposed lower electrode film, the piezoelectric layer being constituted by at least one piezoelectric film formed by conducting a piezoelectric film-forming process of firing a piezoelectric material; and forming an upper electrode film on the piezoelectric layer.

According to this method, a piezoelectric material is applied on the lower electrode film and fired to form a dummy layer, and then the dummy layer is removed and a piezoelectric layer is formed on the lower electrode film. The lower electrode film swells and warps and remains warped even after removal of the dummy layer. The piezoelectric layer is formed on the lower electrode film in the warped state. Thus, heat applied for forming the piezoelectric layer does not make the lower electrode film swell further. Thus, no stress is applied to the piezoelectric layer, and the piezoelectric layer is prevented from cracking due to the stress. Thus, a highly reliable piezoelectric element can be manufactured.

### BRIEF DESCRIPTION OF THE DRAWINGS

The invention will be described with reference to the accompanying drawings, wherein like numbers reference like elements.

FIG. 1 is an exploded perspective view showing an overall structure of a recording head according to one embodiment.

FIG. 2A is a plan view of the recording head and FIG. 2B is a cross-sectional view taken along line IIB-IIB of FIG. 2A.

FIGS. 3A and 3B are cross-sectional views illustrating a method of manufacturing a recording head of one embodiment.

FIGS. 4A to 4D are cross-sectional views illustrating a method of manufacturing a recording head of one embodiment.

FIGS. 5A to 5D are cross-sectional views illustrating a method of manufacturing a recording head of one embodiment.

FIGS. 6A to 6C are cross-sectional views illustrating a method of manufacturing a recording head of one embodiment.

FIGS. 7A to 7C are cross-sectional views illustrating a method of manufacturing a recording head of one embodiment.

FIGS. 8A and 8B are cross-sectional views illustrating a method of manufacturing a recording head of one embodiment.

FIGS. 9A and 9B are cross-sectional views illustrating a method of manufacturing a recording head of one embodiment.

### DESCRIPTION OF EXEMPLARY EMBODIMENTS

Embodiments of the invention will now be described in detail.

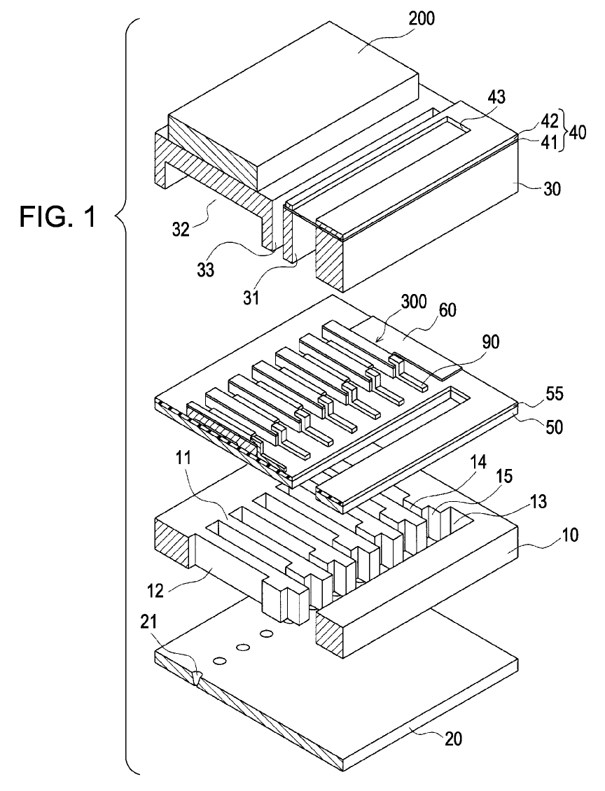

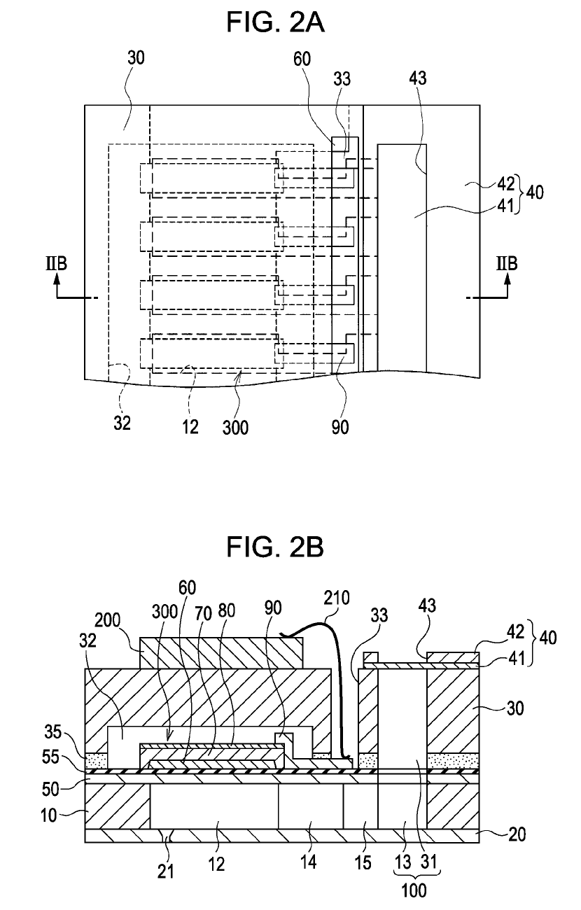

FIG. 1 is an exploded perspective view showing an overall structure of an ink jet recording head, which is one example of a liquid ejection head according to one embodiment. FIG. 2A is a partial plan view of the recording head, and FIG. 2B is a cross-sectional view taken along line IIB-IIB of FIG. 2A.

In this embodiment, a flow channel-forming substrate 10 is a silicon single crystal substrate having a (110) plane orientation. An elastic film 50 made of an oxide film is formed on one surface of the flow channel-forming substrate 10, as shown in the drawings.

The flow channel-forming substrate 10 includes pressure-generating chambers 12 defined by a plurality of dividing walls 11 formed by anisotropically etching the substrate from the opposite side. The pressure-generating chambers 12 are aligned in parallel to each other in the width direction (transverse direction) of the flow channel-forming substrate 10.

Ink supply paths 14 and communication paths 15 are also defined by the dividing walls 11. The ink supply paths 14 and the communication paths 15 are formed at one side of the pressure-generating chambers 12 of the flow channel-forming substrate 10 in the longitudinal direction of the pressure-generating chambers 12.

A communication portion 13 is formed at one ends of the communication paths 15. The communication portion 13 is a part of a reservoir 100 that serves as a common ink reservoir for all pressure-generating chambers 12.

In other words, the flow channel-forming substrate 10 has a liquid flow channel constituted by the pressure-generating chambers 12, the communication portion 13, the ink supply paths 14, and the communication paths 15.

Each ink supply path 14 is communicated with one side of the corresponding pressure-generating chamber 12 in the longitudinal direction and has a cross-sectional area smaller than that of the pressure-generating chamber 12. The ink supply path 14 maintains the flow channel resistance of ink flowing from the communication portion 13 to the pressure-generating chamber 12 constant.

For example, in this embodiment, the ink supply path 14 having a width smaller than that of the pressure-generating chamber 12 is formed by narrowing part of the flow channel at the pressure-generating chamber 12-side between the reservoir 100 and the pressure-generating chamber 12. Although the ink supply path 14 of this embodiment is formed by narrowing the flow channel from one side, the ink supply path 14 may alternatively be formed by narrowing the flow channel from both sides. The ink supply path 14 may be formed by decreasing the thickness of the flow channel instead of decreasing the width of the flow channel.

Each communication path 15 is communicated with the ink supply path 14 at the side remote from the pressure-generating chamber 12 and has a cross-sectional area larger than that of the ink supply path 14 in the width direction (transverse direction) of the ink supply path 14. In this embodiment, the communication path 15 has the same cross-sectional area as the pressure-generating chamber 12.

In other words, the flow channel-forming substrate 10 includes the pressure-generating chambers 12, the ink supply paths 14 each having a cross-sectional area smaller than that of the pressure-generating chamber 12 in the transverse direction, and the communication paths 15 each having a cross-sectional area larger than that of the ink supply path 14 in the transverse direction. The pressure-generating chambers 12, the ink supply paths 14, and the communication paths 15 are defined by a plurality of dividing walls 11.

A nozzle plate 20 having nozzle openings 21 each of which is communicated with an end portion of the pressure-generating chamber 12 opposite to the ink supply path 14 is affixed with an adhesive, a heat-welding film, or the like, onto the opening face-side of the flow channel-forming substrate 10. The nozzle plate 20 is composed of a glass ceramic, silicon single crystals, stainless steel, or the like, for example.

The elastic film 50 is formed at the side of the flow channel-forming substrate 10 opposite to the opening surface, as described above. An insulating film 55 composed of an oxide material different from that of the elastic film 50 is formed on the elastic film 50.

A lower electrode film 60, a piezoelectric film 70, and an upper electrode film 80 are laminated on the insulating film 55 by the process described below. The lower electrode film 60, the piezoelectric film 70, and the upper electrode film 80 constitute a piezoelectric element 300. In other words, the term “piezoelectric element 300” refers to a unit that includes the lower electrode film 60, the piezoelectric film 70, and the upper electrode film 80.

In general, one of the electrodes of each piezoelectric element 300 is formed as a common electrode. The other electrode is formed as an individual electrode by patterning together with the piezoelectric film 70 so that one individual electrode and one piezoelectric film 70 is provided for every pressure-generating chamber 12.

In this embodiment, the lower electrode film 60 is formed as a common electrode of the piezoelectric element 300, and the upper electrode film 80 is used as an individual electrode of the piezoelectric element 300. Such an arrangement may be reversed depending on arrangements of the driving circuit and wiring.

In this embodiment, the piezoelectric element 300 and a diaphragm or diaphragms that undergo displacement while the piezoelectric element 300 is being driven are together referred to as an “actuator device”.

In the example described above, the elastic film 50, the insulating film 55, and the lower electrode film 60 serve as diaphragms, but other arrangements are also possible without any limitation. For example, the elastic film 50 and the insulating film 55 may be omitted and only the lower electrode film 60 may function as a diaphragm. Alternatively, the piezoelectric element 300 itself may substantially function as a diaphragm also.

The piezoelectric film 70 is composed of a piezoelectric material that exhibits an electromechanical transducer function, in particular, a ferroelectric material having a perovskite structure, and is formed on the lower electrode film 60. The piezoelectric film 70 is preferably composed of a ferroelectric material, e.g., lead zirconate titanate (PZT) undoped or doped with a metal oxide such as niobium oxide, nickel oxide, magnesium oxide, or the like.

Specific examples of the material of the piezoelectric film 70 include lead titanate (PbTiO₃), lead zirconate titanate (Pb (Zr, Ti) O₃) lead zirconate (PbZrO₃) lead lanthanum titanate ((Pb, La), TiO₃), lead lanthanum zirconate titanate ((Pb, La) (Zr, Ti) O₃), and lead magnesium niobate zirconium titanate (Pb (Zr, Ti) (Mg, Nb) O₃).

A lead electrode 90 composed of gold (Au) or the like is connected to the upper electrode film 80 that functions as the individual electrode of the piezoelectric element 300. The lead electrode 90 extends from an end portion of the upper electrode film 80 at the ink supply path 14-side to the insulating film 55.

A protective substrate 30 having a reservoir portion 31 which constitutes at least part of the reservoir 100 is joined with an adhesive 35 onto the flow channel-forming substrate 10 with the piezoelectric element 300 thereon, i.e., on the lower electrode film 60, the insulating film 55, and the lead electrode 90.

The reservoir portion 31 of this embodiment penetrates the protective substrate 30 in the thickness direction and extends in the width direction of the pressure-generating chambers 12. As described above, the reservoir portion 31 is part of the reservoir 100 which serves as a common ink reservoir for the pressure-generating chambers 12 while being communicated with the communication portion 13 of the flow channel-forming substrate 10.

Alternatively, only the pressure-generating chambers 12 may be formed in the flow channel-forming substrate 10, and a reservoir 100, constituted by a reservoir portion 31, and an ink supply path communicated with each pressure-generating chamber 12 may be formed in a component (e.g., elastic film 50, insulating film 55, or the like) interposed between the flow channel-forming substrate 10 and the reservoir-forming substrate 30.

Furthermore, for example, only the pressure-generating chambers 12 may be formed in the flow channel-forming substrate 10 and the ink supply paths 14 that connect the reservoir and the pressure-generating chambers 12 may be formed in a member (e.g., elastic film 50, the insulating film 55, or the like) interposed between the flow channel-forming substrate 10 and the protective substrate 30.

A piezoelectric element holder 32 having a space large enough not to inhibit movements of the piezoelectric element 300 is formed in the region of the protective substrate 30 opposing the piezoelectric elements 300.

The piezoelectric element holder 32 needs to have a space large enough not to inhibit movements of the piezoelectric element 300, and this space may be hermetically sealed or left unsealed.

The protective substrate 30 is preferably composed of a material having substantially the same thermal expansion coefficient as the flow channel-forming substrate 10, e.g., glass, a ceramic material, or the like. In this embodiment, the protective substrate 30 is made of a silicon single crystal substrate, which is the same as the flow channel-forming substrate 10.

A through hole 33 that penetrates the protective substrate 30 in the thickness direction is formed in the protective substrate 30. An end portion of the lead electrode 90 extending from the corresponding piezoelectric element 300 is exposed in the through hole 33.

A driving circuit 200 for driving the piezoelectric elements 300 aligned in parallel with each other is affixed onto the protective substrate 30. The driving circuit 200 may be, for example, a circuit substrate or a semiconductor integrated circuit (IC). The driving circuit 200 is electrically connected to each lead electrode 90 via an interconnection wire 210 such as a conductive wire, e.g., a bonding wire.

A compliance substrate 40 including a sealing film 41 and a fixing plate 42 is joined onto the protective substrate 30.

The sealing film 41 is composed of a flexible material having a low rigidity (e.g., polyphenylene sulfide (PPS) film). The sealing film 41 seals one side of the reservoir portion 31. The fixing plate 42 is composed of a hard material such as metal (e.g., SUS stainless steel or the like). The part of the fixing plate 42 opposing the reservoir 100 is completely removed in the thickness direction to form an opening 43. One side of the reservoir 100 is sealed with the flexible sealing film 41 only.

According to the ink jet recording head of this embodiment, ink is taken in from an ink inlet connected to an external ink supply unit (not shown) to fill the interior, i.e., the reservoir 100, the nozzle openings 21, etc., with the ink. Subsequently, in response to a recording signal from the driving circuit 200, voltage is applied between the lower electrode film 60 and the upper electrode film 80 corresponding to the pressure-generating chamber 12. As the elastic film 50, the insulating film 55, the lower electrode film 60, and the piezoelectric film 70 undergo flexural deformation, the pressure inside each pressure-generating chamber 12 increases, and ink droplets are ejected from the nozzle opening 21.

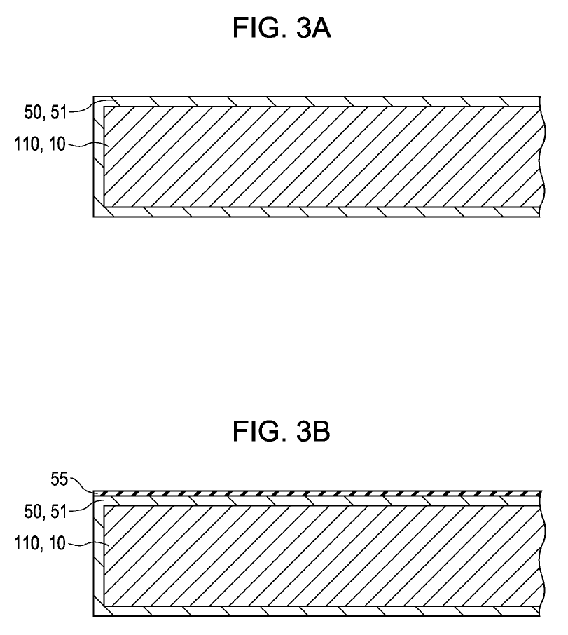

A method of manufacturing such an ink jet recording head will now be described with reference to FIGS. 3A to 9B. FIGS. 3A to 9B are each a cross-sectional view of the pressure-generating chamber 12 taken in the longitudinal direction and illustrate a method of manufacturing an ink jet recording head, which is an example of the liquid ejection head of this embodiment.

First, as shown in FIG. 3A, an oxide film 51 that forms the elastic film 50 is formed on a silicon wafer in which a plurality of flow channel-forming substrates 10 are collectively formed. This wafer for forming flow channel-forming substrates 10 is hereinafter referred to as a “first wafer 110”. The method of forming the oxide film 51 is not particularly limited. For example, the first wafer 110 may be thermally oxidized in a diffusion furnace or the like.

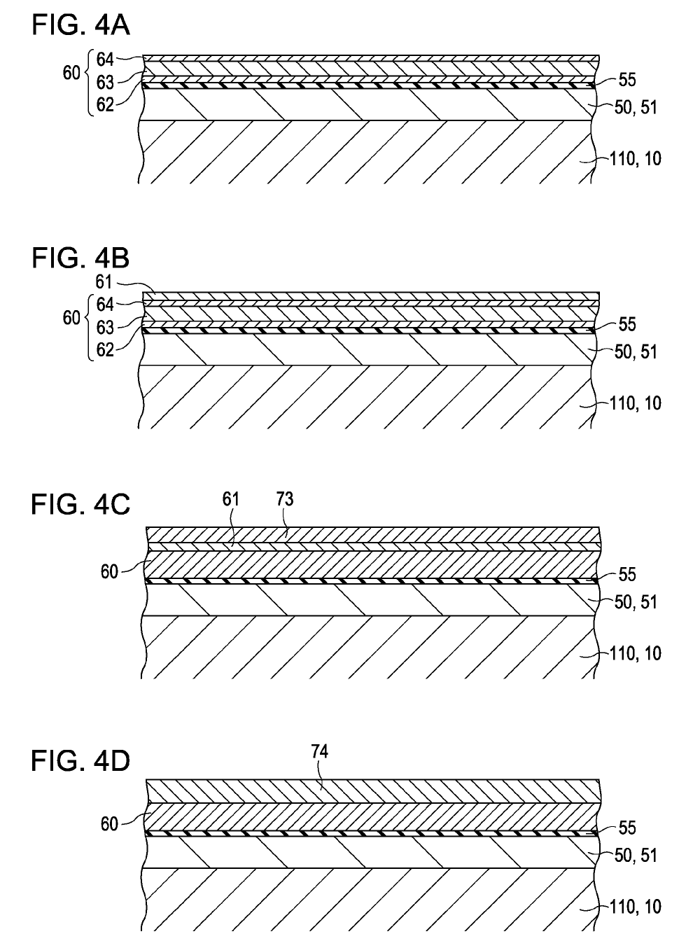

Next, as shown in FIG. 3B, an insulating film 55 made of an oxide film different from the elastic film 50 is formed on the elastic film 50 (oxide film 51). Then, as shown in FIG. 4A, a lower electrode film 60 constituted by an adhesive layer 62, a platinum layer 63, and a diffusion-suppressing layer 64 is formed.

To be more specific, first, the adhesive layer 62 is formed on the insulating film 55. The adhesive layer 62 may contain at least one element selected from the group consisting of titanium (Ti), chromium (Cr), tantalum (Ta) zirconium (Zr), and tungsten (W) as a main component. In this embodiment, the adhesive layer 62 is formed of titanium (Ti). Providing the adhesive layer 62 as the lowermost layer of the lower electrode film 60 can increase the adhesiveness between the insulating film 55 and the lower electrode film 60.

Next, the platinum layer 63 composed of platinum (Pt) is formed on the adhesive layer 62, and the diffusion-suppressing layer 64 is then formed on the platinum layer 63. As a result, a lower electrode film 60 constituted by the adhesive layer 62, the platinum layer 63, and the diffusion-suppressing layer 64 is formed.

The diffusion-suppressing layer 64 suppresses diffusion of the components in the adhesive layer 62 into the piezoelectric film 70 during crystallizing the piezoelectric film 70 under firing in the subsequent step. The diffusion-suppressing layer 64 also suppresses diffusion of lead components of the piezoelectric film 70 into the lower electrode film 60.

The diffusion-suppressing layer 64 may contain at least one metal selected from the group consisting of iridium (Ir), palladium (Pb), rhodium (Rh), ruthenium (Ru) and osmium (Os) or an oxide thereof as a main component. In this embodiment the diffusion-suppressing layer 64 is composed of iridium (Ir).

The layers 62 to 64 of the lower electrode film 60 can be formed by, for example, DC magnetron sputtering.

Next, as shown in FIG. 4B, a protective film 61 is formed on the diffusion-suppressing layer 64. The protective film 61 may be formed by, for example, DC magnetron sputtering. Providing the protective film 61 on the diffusion-suppressing layer 64, which is the uppermost layer of the lower electrode film 60, suppresses incomplete oxidation of iridium contained in the diffusion-suppressing layer 64. As a result, crystals of the piezoelectric film 70 can satisfactorily grow in the subsequent step.

For example, if the first wafer 110 is exposed to air after formation of the lower electrode film 60 on the first wafer 110 in a processing chamber and before formation of a dummy layer, iridium may be incompletely oxidized.

Next, a dummy layer 74 is formed on the protective film 61.

To be more specific, a dummy layer 74 composed of a piezoelectric material having an electromechanical transducer function, in particular, a ferroelectric material having a perovskite structure, is formed.

In this embodiment, the dummy layer 74 is formed by a sol-gel method, in which a sol of a metalorganic material dissolved or dispersed in a solvent is applied and dried to achieve gelation and the resulting gel is fired at a high temperature to obtain a dummy layer composed of a metal oxide. The method for making the dummy layer 74 is not limited to the sol-gel method. A metal organic decomposition (MOD) method may be employed.

The steps of forming the dummy layer 74 will now be specifically described. First, as shown in FIG. 4C, a piezoelectric precursor film 73 is formed on the protective film 61.

In other words, a sol (solution) containing a metalorganic compound is first applied on the protective film 61 (application step) to form the piezoelectric precursor film 73. The piezoelectric precursor film 73 is then heated to a particular temperature and dried for a predetermined time (drying step). The dried piezoelectric precursor film 73 is then heated to a particular temperature and maintained thereat for a predetermined time to conduct degreasing (degreasing step).

Note that “degreasing” means that organic components contained in the piezoelectric precursor film 73 are removed as, for example, NO₂, CO₂, H₂O, or the like.

Next, as shown in FIG. 4D, the piezoelectric precursor film 73 is fired. When fired, the piezoelectric precursor film 73 is crystallized and form a piezoelectric film, which serves as the dummy layer 74.

The heat during firing of the piezoelectric precursor film 73 oxidizes iridium (Ir) constituting the diffusion-suppressing layer 64 into iridium dioxide (IrO₂). The diffusion-suppressing layer 64 need not be completely oxidized into iridium dioxide (IrO₂), and iridium (Ir) may remain unoxidized in some parts.

As the piezoelectric precursor film 73 is transformed into a piezoelectric film by crystallization under firing, the protective film 61 disperses into the piezoelectric film.

As described above, the first wafer 110 warps due to the heat of firing the piezoelectric precursor film 73 because of the difference in linear expansion coefficient between the first wafer 110 and the elastic film 50, the insulating film 55, the lower electrode film 60, and the dummy layer (piezoelectric film) 74 formed on the first wafer 110. Stresses caused by the warpage are also applied to dummy layer 74 and other layers.

As iridium is oxidized into iridium dioxide, the lower electrode film 60 swells and stresses are applied to the dummy layer 74 by warpage of the lower electrode film 60 caused by the swelling.

Moreover, due to interdiffusion between the layers 62 to 64, stresses are applied on the lower electrode film 60. As a result, stresses are applied on the dummy layer 74 also.

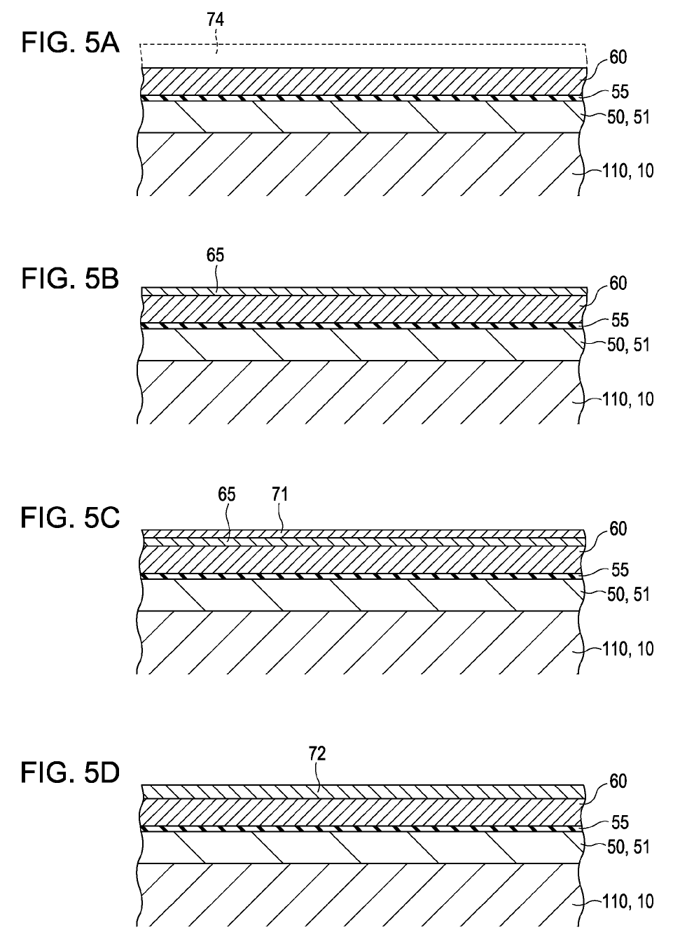

Next, as shown in FIG. 5A, the dummy layer 74 is removed.

To be more specific, the dummy layer 74 is removed with hydrochloric acid (HCl) to expose the lower electrode film 60. After removal of the dummy layer 74, the lower electrode film 60 remains warped. If a piezoelectric film 70 is formed on the lower electrode film 60 in a warped state as described below, no stress is applied on the piezoelectric film 70, and the piezoelectric film 70 is prevented from cracking.

It should be noted that if the lower electrode film 60 alone is heated after formation of the lower electrode film 60 (see FIG. 4A), the lower electrode film 60 does not maintain a warped state. If the lower electrode film 60 does not maintain the warped state, the lower electrode film 60 will warp during formation of the piezoelectric film 70 on the lower electrode film 60, and stresses are applied on the piezoelectric film 70.

In order to prevent lead contained in the dummy layer 74 or the piezoelectric film 70 formed in the step described below from diffusing into the lower electrode film 60, the diffusion-suppressing layer 64 is preferably converted to iridium dioxide. However, it has been found that iridium contained in the diffusion-suppressing layer 64 does not form an iridium dioxide film if the lower electrode film 60 is heated after formation of the lower electrode film 60 (see FIG. 4A). Thus, by providing a dummy layer that promotes oxidation of iridium by supplying oxygen to iridium on the diffusion-suppressing layer 64, iridium is converted into iridium dioxide by heat generated during heating of the dummy layer. The dummy layer is preferably a piezoelectric film formed by firing an applied piezoelectric material.

The dummy layer 74 is provided based on the findings described above. When a piezoelectric film is formed by applying a piezoelectric material and firing the applied material on the diffusion-suppressing layer and this piezoelectric film is used as the dummy layer 74, a diffusion-suppressing layer 64 composed of iridium dioxide can be substantially unfailingly obtained.

Next, as shown in FIG. 5B, a titanium layer 65 composed of titanium (Ti) is formed on the lower electrode film 60.

The titanium layer 65 may be formed by, for example, DC magnetron sputtering. The titanium layer 65 is preferably amorphous. Formation of such a titanium layer 65 will help control the preferential orientation direction of the piezoelectric film 70 to (100) or (111) in a subsequent step of forming the piezoelectric film 70 on the titanium layer 65 on the lower electrode film 60. Thus, a piezoelectric film 70 suitable for an electromechanical transducer can be obtained.

The titanium layer 65 functions as a seed for promoting crystallization during the process of crystallizing the piezoelectric film 70. The titanium layer 65 diffuses into the piezoelectric film 70 after firing of the piezoelectric film 70.

Next, the piezoelectric film 70 composed of lead titanate zirconate (PZT) is formed. The piezoelectric film 70 of this embodiment is formed by a sol-gel method as with the dummy layer 74. The method for making the piezoelectric film 70 is not limited to the sol-gel method. A metal organic decomposition (MOD) method may be employed.

The steps of forming the piezoelectric film 70 will now be specifically described. First, as shown in FIG. 5C, a piezoelectric precursor film 71 is formed on the lower electrode film 60 (titanium layer 65). In other words, a sol (solution) containing a metalorganic compound is applied on the flow channel-forming substrate 10 with the protective film 60 thereon (application step). The resulting piezoelectric precursor film 71 is heated to a particular temperature and dried for a predetermined time (drying step). For example, in this embodiment, the piezoelectric precursor film 71 can be dried by retaining it at 170° C. to 180° C. for 8 to 30 minutes. The dried piezoelectric precursor film 71 is then heated to a particular temperature and maintained thereat for a predetermined time to conduct degreasing (degreasing step).

For example, in this embodiment, the piezoelectric precursor film 71 is degreased by holding the piezoelectric precursor film 71 at a temperature of about 300° C. to 400° C. for about 5 to 10 minutes. Note that “degreasing” means that organic components contained in the piezoelectric precursor film 71 are removed as, for example, NO₂, CO₂, H₂O, or the like.

Next, as shown in FIG. 5D, the piezoelectric precursor film 71 is heated to a particular temperature and retained thereat for a predetermined time to crystallize the piezoelectric precursor film 71 into a piezoelectric film 72 (firing step).

In the firing step, the piezoelectric precursor film 71 is preferably heated to 680° C. to 900° C. In this embodiment, the piezoelectric precursor film 71 is heated at 680° C. for 5 to 30 minutes to form the piezoelectric film 72.

The heating apparatus used in the drying, degreasing, and firing steps may be a hot plate, a rapid thermal processing apparatus that heats the workpiece by irradiation with infrared lamp, or any other suitable apparatus.

During firing of the piezoelectric precursor film 71, the lower electrode film 60 is also heated. However, the lower electrode film 60 is substantially prevented from warping any further. This is because in forming the dummy layer 74 by firing the piezoelectric precursor film 73, iridium contained in the diffusion-suppressing layer 64 of the lower electrode film 60 is oxidized into iridium dioxide and thus the lower electrode film 60 does not swell further. Thus, the lower electrode film 60 does not undergo oxidation and swelling by the heat applied during firing of the piezoelectric precursor film 71. In other words, the lower electrode film 60 does not warp any further by firing of the piezoelectric precursor film 71.

Accordingly, no stress is applied on the piezoelectric film 72, and the cracks in the piezoelectric film 72 caused by the stress are prevented.

The amount of lead contained in the piezoelectric material used in forming the dummy layer 74 is preferably adjusted so that the lead content in the piezoelectric material of the dummy layer 74 is lower than that of the piezoelectric film 70. Preferably, the piezoelectric material that forms the dummy layer 74 is free of lead.

The lead content in the dummy layer 74 is preferably as low as possible or zero to suppress diffusion of lead into the lower electrode film 60. Because the diffusion-suppressing layer 64 is included in the lower electrode film 60, diffusion of lead components in the piezoelectric film 70 into the lower electrode film 60 can be more assuredly prevented. As a result, the piezoelectric characteristics of the piezoelectric film 70 can be further enhanced.

The lower electrode film 60 does not always have to include the diffusion-suppressing layer 64. In the cases where the lower electrode film 60 does not include the diffusion-suppressing layer 64, the lead content in the dummy layer 74 is preferably as low as possible or zero.

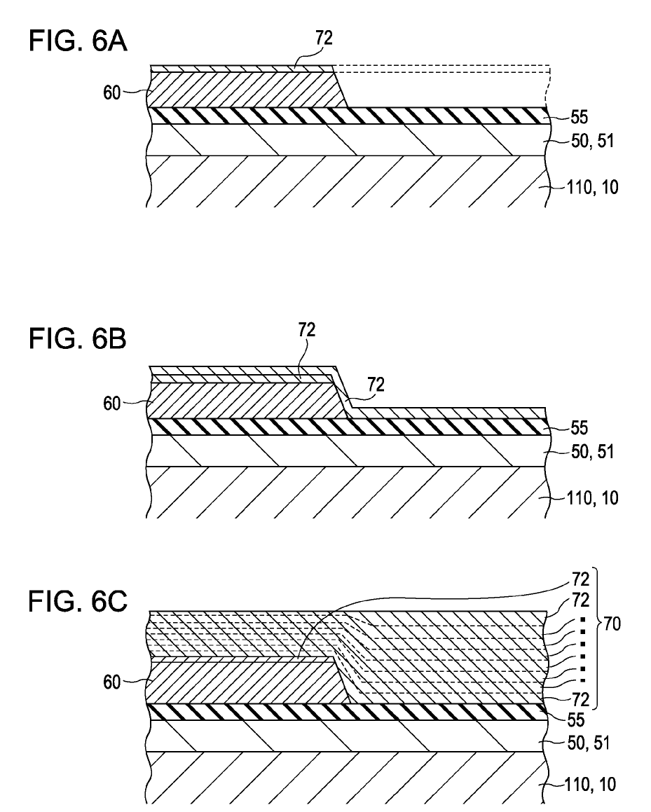

Next, as shown in FIG. 6A, after the piezoelectric film 72, i.e., the first layer, is formed on the lower electrode film 60, the lower electrode film 60 and the first piezoelectric film 72 are simultaneously patterned so that their side faces are sloped.

According to this arrangement, in forming a second piezoelectric film 72, adverse effects on crystallinity of the second piezoelectric film 72 caused by difference in the base layer can be reduced or minimized in the border region between the portion where the lower electrode film 60 and the first piezoelectric film 72 are formed and the portion other than this portion. Accordingly, the crystal growth of the second piezoelectric film 72 progresses satisfactorily in the border region between the lower electrode film 60 and other region, and a piezoelectric film 70 having a high crystallinity can be formed.

Since the side faces of the lower electrode film 60 and the first piezoelectric film 72 are sloped, the throwing power during formation of the second and subsequent piezoelectric films 72 can be improved. Accordingly, a piezoelectric film 70 having high adhesiveness and reliability can be formed.

The lower electrode film 60 and the first piezoelectric film 72 can be patterned by, for example, dry etching such as ion milling or the like.

Next, as shown in FIG. 6B, a piezoelectric film forming process including the application, drying, degreasing, and firing steps described above is conducted on the first wafer 110 and the first piezoelectric film 72 to form the second piezoelectric film 72. Then, as shown in FIG. 6C, the piezoelectric film forming process including the application, drying, degreasing, and firing steps described above is repeated on the second piezoelectric film 72 to form a plurality of piezoelectric films 72.

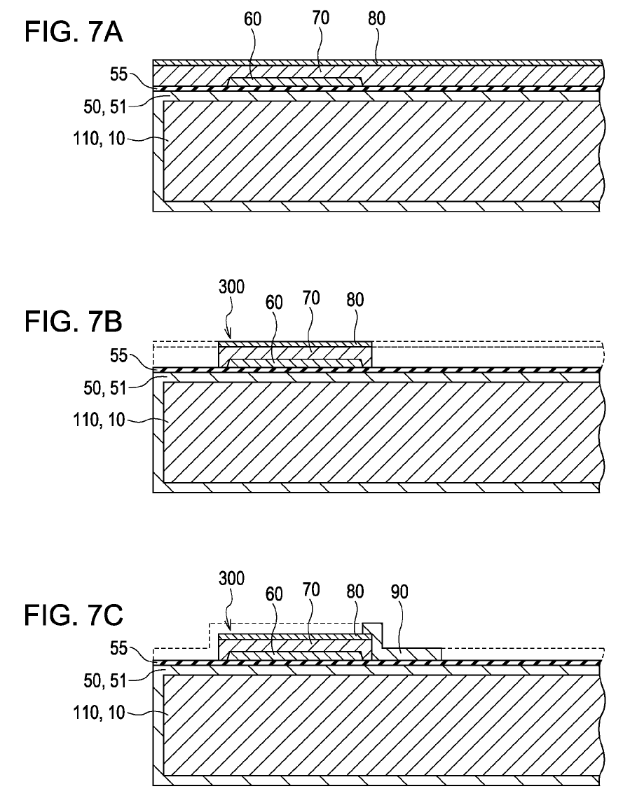

As shown in FIG. 7A, the upper electrode film 80 composed of, for example, iridium (Ir) is formed over the piezoelectric film 70 constituted by a plurality of piezoelectric films 72. The piezoelectric film 70 and the upper electrode film 80 are subjected to patterning to form the piezoelectric elements 300 in a region opposing the pressure-generating chambers 12, as shown in FIG. 7B.

The piezoelectric film 70 and the upper electrode film 80 may be patterned by, for example, dry etching such as reactive ion etching, ion milling, or the like.

The lead electrode 90 is formed next. In particular, as shown in FIG. 7C, a lead electrode 90 composed of gold (Au) or the like is first formed over the entire surface of the first wafer 110 and then patterned through a mask pattern (not shown) composed of resist or the like to form lead electrodes 90 corresponding to the piezoelectric elements 300.

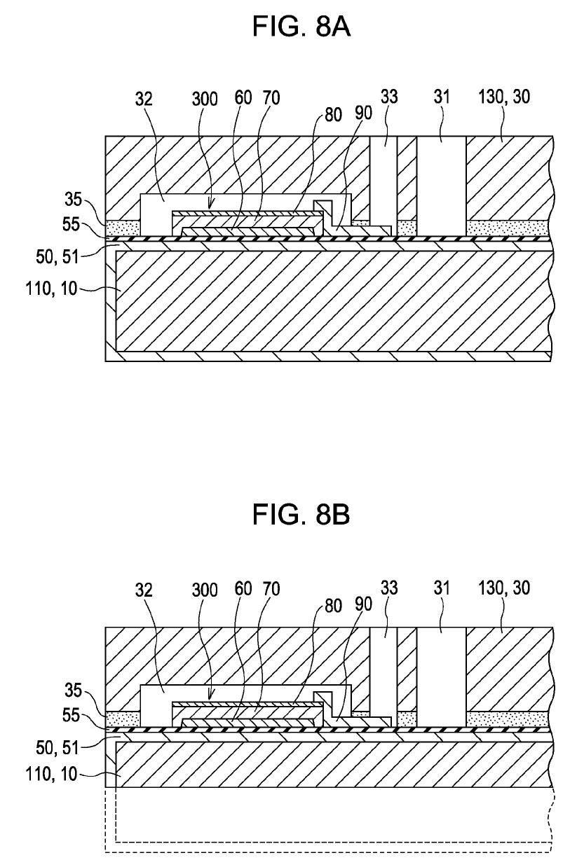

As shown in FIG. 8A, a silicon wafer for forming a plurality of protective substrates 30 (this wafer is hereinafter referred to as “second wafer 130”) is joined onto the piezoelectric element 300-side of the first wafer 110. Then, as shown in FIG. 8B, the thickness of the first wafer 110 is decreased to a particular level.

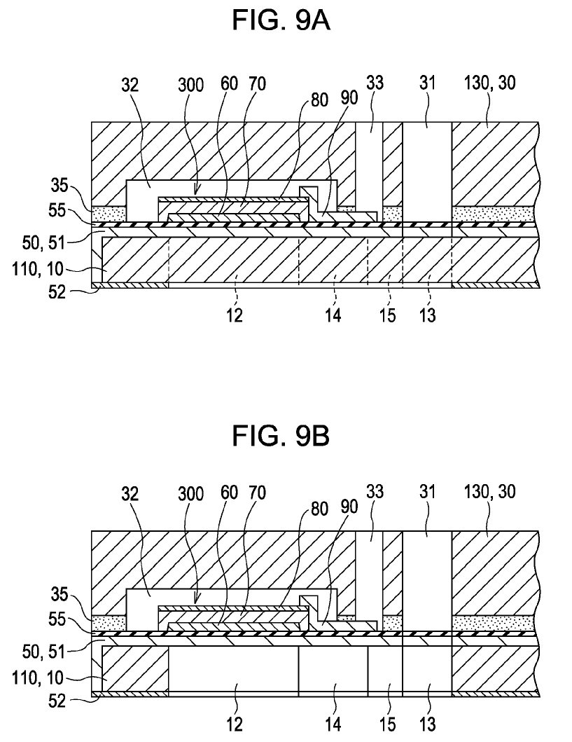

A new mask film 52 is formed on the first wafer 110 and patterned into a predetermined shape, as shown in FIG. 9A.

The first wafer 110 is anisotropically etched (wet-etched) with an alkaline solution such as KOH or the like through the mask film 52 to form the pressure-generating chambers 12, the communication portion 13, the ink supply paths 14, and the communication paths 15 corresponding to the piezoelectric elements 300, as shown in FIG. 9B.

Unneeded portions at the outer peripheral portions of the first and second wafers 110 and 130 are removed by cutting, e.g., dicing or the like.

The nozzle plate 20 having the nozzle openings 21 perforated therein are joined onto the surface of the first wafer 110 remote from the second wafer 130. The compliance substrate 40 is joined onto the second wafer 130, and the first wafer 110 and other associated components are diced to separate chip-sized flow channel-forming substrates 10 shown in FIG. 1, etc., to make an ink jet recording head of this embodiment.

As described above, according to the method of making the ink jet recording head of this embodiment, a piezoelectric material is applied on the lower electrode film 60 and fired to form the dummy layer 74, and then the dummy layer 74 is removed and the piezoelectric film 70 is formed on the lower electrode film 60.

As a result, iridium contained in the lower electrode film 60 is oxidized into iridium dioxide and swells. This causes the lower electrode film 60 to warp and the lower electrode film 60 remains warped even after removal of the dummy layer 74.

Since the piezoelectric film 70 is formed on the lower electrode film 60 in a warped state, the piezoelectric film 70 is prevented from being stressed since the warpage of the lower electrode film 60 does not progress further by the heat applied during the step of forming the piezoelectric film 70. Thus, the piezoelectric film 70 is prevented from cracking due to the stress. An ink jet recording head having highly reliable piezoelectric elements 300 can be manufactured.

The description above involves one embodiment of the invention and the basic features of the invention are not limited to those described above.

For example, in the above-discussed embodiment, the diffusion-suppressing layer 64 composed of iridium is formed as the uppermost layer of the lower electrode film 60. However, the uppermost layer need not contain iridium. In cases where the uppermost layer does not contain iridium, there is no need to provide the protective film 61.

The dummy layer 74 is not limited to a single-layer piezoelectric film as described above and may be a multilayer piezoelectric film.

In the embodiment described above, a (110) silicon single crystal substrate is described as an example of the flow channel-forming substrate 10. Alternatively, for example, a (100) silicon single crystal substrate, a silicon-on-insulator (SOI) substrate, a glass substrate, or the like may be used as the flow channel-forming substrate 10.

In the embodiment described above, an ink jet recording head is described as an example of the liquid ejection head. However, the invention has a broad scope covering the entire genre of liquid ejection heads. The invention is naturally applicable to liquid ejection heads that eject liquids other than ink.

Examples of other liquid ejection heads include various recording heads used in image recording apparatuses such as printers, coloring material ejecting heads used in making color filters of liquid crystal displays and the like, electrode material-ejecting heads used in forming electrodes of organic EL displays, field emission displays (FED), and the like, and bioorganic compounds-ejecting heads used in making biochips.

The application range of the invention is not limited to the method of manufacturing piezoelectric elements to be mounted in liquid ejection heads, such as ink jet recording heads. The invention is also applicable to methods of making piezoelectric elements to be incorporated in other types of apparatuses.

What is claimed is:

1. A method of manufacturing a liquid ejection head that includes a flow channel-forming substrate having pressure-generating chambers communicated with nozzle openings configured to eject liquid, and a piezoelectric element including a lower electrode film disposed in a region of the flow channel-forming substrate opposing the pressure-generating chambers, a piezoelectric layer, and an upper electrode film, the method comprising:
forming a lower electrode film at one side of a flow channel-forming substrate;
forming a dummy layer by firing a piezoelectric material on the lower electrode film;
exposing the lower electrode film by removing the dummy layer;
forming a piezoelectric layer on the exposed lower electrode film, the piezoelectric layer being constituted by at least one piezoelectric film formed by conducting a piezoelectric film-forming process of firing a piezoelectric material; and
forming an upper electrode film on the piezoelectric layer.

2. The method according to claim 1, wherein:
the piezoelectric material used in forming the piezoelectric film is a sol of an organometallic compound containing lead; and
the piezoelectric material used in forming the dummy layer is a sol of an organometallic compound that contains no lead or lead in an amount smaller than that contained in the piezoelectric material used for forming the piezoelectric film.

3. The method according to claim 2, wherein:
the lower electrode film includes:
an adhesive layer on the flow channel-forming substrate;
a platinum layer on the adhesive layer; and
a diffusion-suppressing layer configured to suppress diffusion of lead, the diffusion-suppressing layer being disposed on the platinum layer.

4. The method according to claim 3, further comprising:
forming a protective film containing titanium on the diffusion-suppressing layer after forming the lower electrode film.

5. The method according to claim 1, further comprising:
forming a titanium layer on the lower electrode film after removal of the dummy layer.

6. The method according to claim 1, wherein:
in forming the piezoelectric layer, the piezoelectric film-forming process is repeated to form a piezoelectric layer constituted by a plurality of piezoelectric films.

7. The method according to claim 6, wherein:
in forming the piezoelectric layer, after the first piezoelectric film is formed, the lower electrode film and the piezoelectric film are patterned.

8. A method of manufacturing a piezoelectric element including a lower electrode film, a piezoelectric layer, and an upper electrode film, the method comprising:
forming a lower electrode film at one side of a substrate;
forming a dummy layer by firing a piezoelectric material on the lower electrode film;
exposing the lower electrode film by removing the dummy layer;
forming a piezoelectric layer on the exposed lower electrode film, the piezoelectric layer being constituted by at least one piezoelectric film formed by conducting a piezoelectric film-forming process of firing a piezoelectric material; and
forming an upper electrode film on the piezoelectric layer.
